(19) United States
(12) Patent Application Publication
(10) Pub. No.: US 2017/0238425 A1
(43) Pub. Date: Aug. 17, 2017

(54) Method of Fabricating Highly Conductive Features with Silver Nanoparticle Ink at Low Temperature

(71) Applicant: Tyco Electronics Corporation, Berwyn, PA (US)

(72) Inventors: Barry C. Mathews, Fremont, CA (US); Yiliang Wu, San Ramon, CA (US); Miguel A. Morales, Fremont, CA (US); Michael A. Oar, San Francisco, CA (US); Leonard Henry Radzilowski, Palo Alto, CA (US); Juliana B. De Guzman, San Jose, CA (US)

(73) Assignee: Tyco Electronics Corporation, Berwyn, PA (US)

(21) Appl. No.: 15/043,473

(22) Filed: Feb. 12, 2016

(51) Int. Cl. H05K 3/22

(52) U.S. Cl. CPC H05K 3/22

(57) ABSTRACT

A method of fabricating highly conductive (low resistive) features with silver nanoparticle inks at low processing temperature including room temperature is provided, The method includes 1) printing a silver nanoparticle ink to form a conductive feature on a substrate; 2) drying/annealing the printed feature at a temperature compatible with the substrate; 3) treating the annealed feature in a humidity environment; and 4) optionally drying the treated conductive feature. The silver nanoparticle conductive features exhibit a decrease in resistivity from about a factor of 2 up to about a few orders of magnitude after exposure to the humidity treatment.

### FIELD

The present disclosure relates to silver nanoparticle ink compositions and the use thereof. More specifically, this disclosure relates to conductive traces formed from silver nanoparticle inks applied onto plastic substrates that are incorporated as part of an electronic component and methods of enhancing conductivity or reducing resistivity thereto.

### BACKGROUND

The statements in this section merely provide background information related to the present disclosure and may not constitute prior art.

Conductive inks are increasingly being used to form printed elements, such as antennas or sensors, in a variety of 2-D and 3-D electronic applications. Generally, two types of conductive inks are being utilized, namely, polymer thick film (PTF) pastes and metal nanoparticle inks. The PTF pastes are often composed of micron-size metal flakes dispersed in polymer binders. The use of polymer binders allows the cured PTF pastes to adhere to various substrate materials. However, these polymer binders also act as an insulator and have an adverse effect on the conductivity exhibited by the printed conductive elements.

In comparison, the metal nanoparticle inks generally include very little to no amount of polymer binders. Thus upon sintering of the nanoparticle inks, a higher level of conductivity is often obtained. However, this increase in conductivity is obtained at the expense of adhesion to the substrate material. In addition, most metal nanoparticle inks still require a relatively high annealing (or sintering) temperature for example between 150° C. and 250° C. These sintering temperatures are still not compatible with commonly used engineering plastic substrates, including polycarbonate (PC) and polyvinylidene fluoride (PVDF), among others.

The use of plastic substrate materials reduces the sintering temperature that can be utilized to cure the conductive inks to for example, no greater than 120° C. or below 80° C., or even at room temperature under certain conditions. The use of low-cost, temperature sensitive plastic substrates requires the conductive ink to exhibit good adherence of the ink to the substrate along with retaining high conductivity (e.g., low resistivity) upon exposure to a low annealing or sintering temperature.

### SUMMARY

The present disclosure generally provides a method of forming a treated conductive trace on a substrate in order to lower resistivity (i.e., enhance conductivity). The method comprises: providing the substrate; providing a silver nanoparticle ink; applying the silver nanoparticle ink onto the substrate; annealing the silver nanoparticle ink to form an initial conductive trace having a first resistivity (ρ₁); and subjecting the initial conductive trace to a humidified atmosphere for a predetermined amount of time in order to form the treated conductive trace having a second resistivity (ρ₂), wherein ρ₂ is less than ρ₁, alternatively, ρ₂ is less than ρ₁ by at least a factor of 2. The humidity atmosphere comprises between about 40% relative humidity (RH) to about 100% RH at a temperature between about 20° C. to less than 100° C. The predetermined amount of time may be between about 1 minute and about 200 hours.

According to one aspect of the present disclosure, the substrate may be a plastic substrate formed from a polycarbonate, an acrylonitrile butadiene styrene (ABS), a polyamide, or a polyester, a polyimide, vinyl polymer, polystyrene, polyether ether ketone (PEEK), polyurethane, epoxy-based polymer, polyethylene ether, polyether imide (PEI), polyolefin, or a polyvinylidene fluoride (PVDF) substrate. In addition, the method may further comprise applying a primer layer to a surface of the substrate prior to the application of the silver nanoparticle ink and at least partially curing the primer layer. In this case, the silver nanoparticle ink is applied onto the surface of the primer layer.

According to another aspect of the present disclosure, the silver nanoparticle ink is annealed at a temperature that is no more than 120° C. and the method optionally comprises drying the treated conductive trace at a temperature ranging from room temperature up to about 80° C. The silver nanoparticle ink may be applied using an analog or a digital printing method.

According to yet another aspect of the present disclosure, the silver nanoparticle ink comprises silver nanoparticles having an average particle diameter between about 2 nanometers and 800 nanometers. The surface of the silver nanoparticles may be at least partially stabilized with a hygroscopic or water-soluble capping agent. This capping agent may be selected from the group consisting of polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof. The capping agent is at least partially removed from the surface of the silver nanoparticles upon exposure to the humidified atmosphere or treatment.

A functional conductive layered composite may be formed that comprises the conductive trace made according to the teachings described above and further defined herein. The functional conductive layered composite may function as an antenna, an electrode of an electronic device, or an interconnect joining two electronic components.

According to yet another aspect of the present disclosure, a method of forming a functional conductive layered composite comprises: providing a plastic substrate; optionally, applying a primer layer to a surface of the plastic substrate and at least partially curing the primer layer; providing a silver nanoparticle ink; applying the silver nanoparticle ink onto the surface of the plastic substrate or onto the optional primer layer; annealing the silver nanoparticle ink at a temperature at or below 120° C. to form an initial conductive trace that exhibits a first resistivity (ρ₁); and subjecting the initial conductive trace to a humidified atmosphere for a predetermined amount of time in order to form the treated conductive trace, which exhibits a second resistivity (ρ₂) that is less than ρ₁; alternatively, ρ₂ is less than ρ₁ by at least a factor of 2; alternatively, ρ₂ is less than ρ₁ by at least a factor of 10; and incorporating the conductive trace into the functional conductive layered composite. The method, optionally, may further comprise drying the treated conductive trace.

The plastic substrate in the functional conductive layered composite may be selected from the group consisting of a polycarbonate, an acrylonitrile butadiene styrene (ABS), a polyamide, a polyester, a polyimide, vinyl polymer, polystyrene, polyether ether ketone (PEEK), polyurethane, epoxy-based polymer, polyethylene ether, polyether imide (PEI), polyolefin, or a polyvinylidene fluoride (PVDF) substrate.

The silver nanoparticle ink used in forming the functional conductive layered composite comprises silver nanoparticles having an average particle diameter in the range of about 2 nanometers (nm) to about 800 nanometers (nm); alternatively, from about 50 nm to about 300 nm, and a surface that is at least partially stabilized with a hygroscopic or water-soluble capping agent. The capping agent may be selected from the group consisting of polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof. When desirable, the capping agent may be at least partially removed from the surface of the silver nanoparticles upon exposure to the humidified atmosphere.

The humidity atmosphere used in the method of forming the functional conductive layered composite may comprise between about 40% relative humidity (RH) to about 100% RH at a temperature between about 20° C. to about 100° C. The predetermined amount of time may be between about 1 minute and about 200 hours; alternatively, between about 10 minutes and 100 hours; alternatively, between about 1 hour and 24 hours.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

FIG. 1 is a schematic describing a method of enhancing conductivity or reducing resistivity of a conductive trace according to the teachings of the present disclosure.

FIG. 2 is a graphical representation of resistivity exhibited by a silver nanoparticle film coated on polycarbonate substrate annealed at 120° C. for 60 minutes measured before and after humidity aging for 24 hours.

FIG. 3 is a graphical representation of resistivity exhibited by a silver nanoparticle film printed on a PVDF substrate dried at 80° C. for 10 minutes measured before and after humidity aging for 2 minutes.

FIG. 4 is a Fourier Transform Infrared (FTIR) spectrum of yellow spots observed on the surface of a silver nanoparticle film treated according to the teachings of the present disclosure.

FIG. 5 is a schematic illustration describing the effect of the humidity treatment on the silver nanoparticle film according to the teachings of the present disclosure.

### DETAILED DESCRIPTION

The following description is merely exemplary in nature and is not intended to limit the present disclosure, application, or uses. For example, the method made and used in accordance with the teachings contained herein is described throughout the present disclosure in conjunction with polycarbonate substrates commonly utilized in consumer electronic applications in order to more fully illustrate the increased conductivity of the treated silver nanoparticle films and the use thereof. The incorporation and use of the disclosed method to enhance conductivity (i.e., reduce resistivity) of treated silver nanoparticle films on other plastic substrates for use in a variety of applications is contemplated to be within the scope of the present disclosure. It should be understood that throughout the description, corresponding reference numerals or letters indicate like or corresponding parts and features.

The method of the present disclosure generally comprises a process to fabricate highly conductive (low resistive) features with silver nanoparticle inks at low processing temperatures including, but not limited to room temperature up to 120° C. This process generally includes 1) printing a silver nanoparticle ink to form a conductive feature on a substrate; 2) annealing the printed feature at a temperature compatible with the substrate; 3) treating the annealed feature in a humidity environment; and optionally, 4) drying the treated conductive feature. The silver nanoparticle conductive features treated according to the teachings of the present disclosure exhibit a decrease in resistivity by about a factor of 2 to about a few orders of magnitude after exposure to the humidity treatment; alternatively, the resistivity after humidity treatment is less than 5.0×10⁻⁵ ohms cm.

One benefit of utilizing the process of the present disclosure is to fabricate conductive features at a low temperature, including room temperature up to no more than 120° C. The concept may utilize any commercially available silver nanoparticle ink including inks comprising, without limitation, polyvinylpyrrolidone (PVP) stabilized silver nanoparticles. Without wanting to be limited to any theory, it is believed that the humidity leaches out or dissolves the water soluble capping polymer, dispersant, or other surface treatment present on the surface of the silver nanoparticles, leading to more effective particle to particle contact and a lower resistivity.

The use of metal nanoparticle inks may provide several advantages when compared to conventional Polymer Thick Film technology in forming conductive traces. First, metal nanoparticles inks usually do not contain any significant amount of polymeric binders. Thus, upon sintering, metal nanoparticle inks offer the potential of exhibiting higher conductivity. Second, the small particle size associated with the metal nanoparticles enables the use of metal nanoparticle inks in a variety of printing techniques, including inkjet and aerosol jet printing where small nozzles are utilized. Third, also due to the characteristic of small particle size, films formed from metal nanoparticle inks usually exhibit very low surface roughness, which is an important characteristic for multiple-layered device integration.

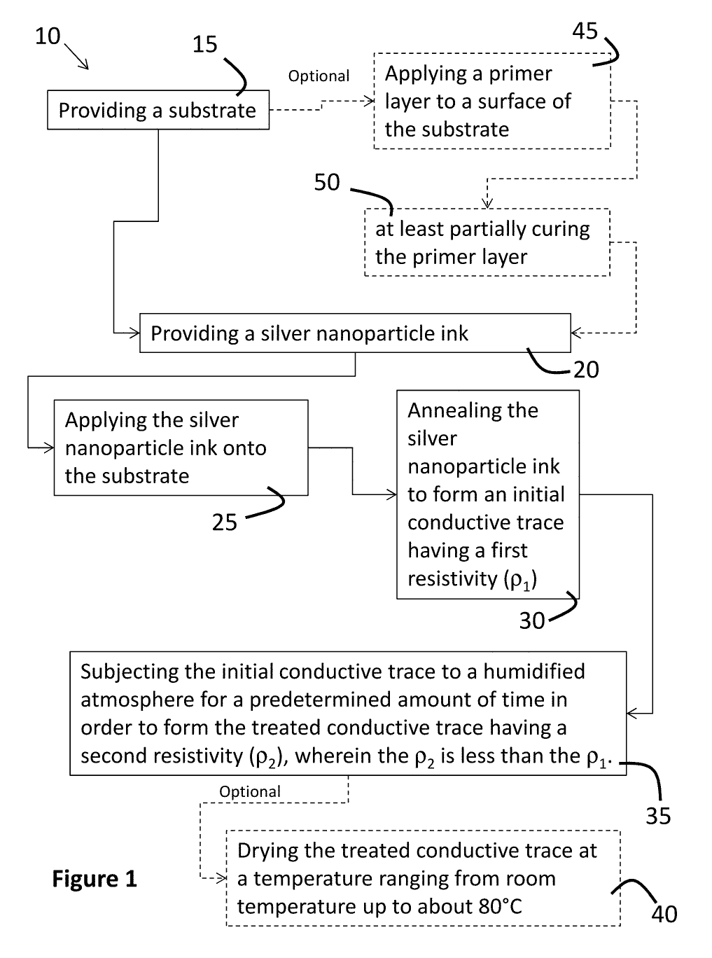

Referring now to FIG. 1, the method 10 comprises, consists of, or consists essentially of providing 15 a substrate; providing 20 a silver nanoparticle ink; applying 25 the silver nanoparticle ink onto the substrate; annealing 30 the silver nanoparticle ink to form an initial conductive trace having a first resistivity (ρ₁); subjecting 35 the initial conductive trace to a humidified atmosphere for a predetermined amount of time in order to form a treated conductive trace having a second resistivity (ρ₂), wherein ρ₂ is less than the ρ₁, alternatively, ρ₂ is less than ρ₁ by at least a factor of 2; alternatively, ρ₂ is less than ρ₁ by at least a factor of 5; alternatively, ρ₂ is less than ρ₁ by at least a factor of 10. Optionally, the method 10 may further comprise drying 40 the treated conductive trace at a temperature ranging from room temperature up to about 80° C.; alternatively, from room temperature to about 60° C. For the purpose of this disclosure, the term “conductive trace” refers to any conductive elements in any suitable shapes such as a dot, a pad, a line, a layer, and the like.

Still referring to FIG. 1, the method 10 may also include applying 45 a primer layer to a surface of the substrate and at least partially curing 50 the primer layer. In this case, the silver nanoparticle ink is applied onto the primer layer. The primer layer may be any type of material applied to the surface of the substrate in order to enhance one or more properties associated with the silver nanoparticle ink, such as but not limited to adhesion. Several specific examples of such a primer layer include without limitation the alkoxysilane additive described in co-pending, commonly assigned U.S. patent application Ser. No. ______, entitled “Method for Enhancing Adhesion of Silver Nanoparticle Inks Using a Functionalized Alkoxysilane Additive and Primer Layer”, and the poly(vinyl butyral) copolymer described in co-pending, commonly assigned U.S. patent application Ser. No. ______, entitled “Method of Enhancing Adhesion of Silver Nanoparticle Inks on Plastic Substrates Using a Cross-linked Poly(vinyl butyral) Primer Layer”, both filed contemporaneously with this application, and the contents of both being hereby incorporated in their entirety by reference.

In general, printing technologies can be divided into two major categories, namely, analog printing and digital printing. Several examples of analog printing include, without limitation, flexographic, gravure, and screen printing. Several examples of digital printing include, but are not limited to, inkjet, aerosol jet, disperse jet, and drop-on-demand techniques. While analog printing offers high printing speed, digital printing enables the facile change of printed pattern designs, which may find use in the field of personalized electronics. Among the digital printing technologies, aerosol jet and disperse jet are attractive due to their large distance between the nozzle and the substrate surface. This characteristic allows conformal deposition of conductive inks on substrates that exhibit a topographic structure. When integrated with a 5-axis motion-control stage or robotic arm, aerosol jet and dispense jet can be used to print conductive elements onto 3-D surfaces.

The silver nanoparticle inks can be applied onto the substrate or the optional at least partially cured primer layer using any analog or a digital printing method, including, but not limited to inkjet printing, aerosol-jet printing, dispense jet printing, flexographic printing, gravure printing, screen printing, or stencil printing. Other coating methods, including, without limitation, spin coating, dip coating, doctoral blade coating, slot die coating can also be used. The silver nanoparticle ink may have a viscosity that is predetermined by the application process, for example from a few milliPascal-seconds (mPa-sec) or centipoise (cps) to about 20 mPa-sec for an inkjet printing process, or from about 50 mPa-sec to about 1000 mPa-sec for aerosol jet, flexographic, or gravure printing processes, or above 10,000 mPa-sec for screen and stencil printing processes. Alternatively, the silver nanoparticle ink can be printed onto 3-D surfaces using aerosol jet and/or dispense jet printing techniques, or printed onto 2-D surfaces using a screen printing method. When desirable, the surface of the substrate may be treated using an atmospheric/air plasma, a flame, an atmospheric chemical plasma, a vacuum chemical plasma, UV, UV-ozone, heat treatment, solvent treatment, mechanical treatment, such as roughening the surface with sand paper, abrasive blasting, water jet, and the like, or a corona discharging process prior to the application of the primer layer.

The ability to apply the silver nanoparticle inks to a plastic substrate using an additive printing technique offers several advantages, such as fast turn-around time and quick prototyping capability, easy modification of device designs, and potentially lower-manufacturing costs due to reducing material usage and the number of manufacturing steps. The direct printing of conductive inks also enables the use of thinner substrates when forming light-weight devices. Additive printing may also be a more environmentally friendly approach due to the reduced chemical waste generated in the device manufacturing process, when compared to conventional electroplating or electroless plating processes.

The plastic substrate may be a polycarbonate, an acrylonitrile butadiene styrene (ABS), a polyamide, a polyester, a polyimide, vinyl polymer, polystyrene, polyether ether ketone (PEEK), polyurethane, epoxy-based polymer, polyethylene ether, polyether imide (PEI), polyolefin, a polyvinylidene fluoride (PVDF), or a copolymer thereof. A specific example of a polyether imide and a polycarbonate substrate are Ultem™ (SABIC Innovative Plastics, Massachusetts) and Lexan™ (SABIC Innovative Plastics, Massachusetts), respectively. Alternatively, the substrate is a polycarbonate or a PVDF substrate.

The silver nanoparticles may be fused together upon annealing at the desired temperature. Alternatively, the silver nanoparticles can be not properly sintered together, especially at the interface region, at the predetermined annealing temperature, which is determined according to the properties of the substrate or other layers that are pre-deposited on to the substrate. For example, in order to reduce degradation or deformation of a polycarbonate substrate the annealing temperature should be no more than 120° C., similarly, the annealing temperature should be room temperature up to 80° C. when a PVDF substrate is utilized. According to some aspects of the present disclosure, a majority of the silver nanoparticles are not fused together upon annealing. In these cases, the average particle diameter of the silver nanoparticles in the conductive trace after annealing is substantially the same as that in the silver nanoparticle ink. According to other aspects of the present disclosure, a minority of the silver nanoparticles are not fused together upon annealing. Alternatively, at least 5 wt. %, alternatively at least 10 wt. %, or alternatively at least 40 wt. % silver nanoparticles are not fused together. The weight percentage can be measured by extracting the annealed silver nanoparticle conductive layer with a solvent that is compatible with the nanoparticles and calculating the weight loss.

The silver nanoparticles in the silver nanoparticle ink may have a particle size within the range of about 2 nanometers (nm) to about 800 nm; alternatively, from about 50 nm to about 800 nm; alternatively, from about 80 nm to about 300 nm. The silver nanoparticles may also optionally have a hydrophilic coating or a hygroscopic or water-soluble capping agent applied to at least part of the particles' surface. The silver nanoparticles may be stabilized with a hygroscopic and/or water-soluble capping agent, such as, without limitation, polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof. In this case, the silver nanoparticles are dispersible in polar solvent such as alcohol, or even water. The amount of capping agent can be for example from about 0.5 wt. % to about 10 wt. %, alternatively, from about 0.5 wt. % to about 5 wt. %, or alternatively, from about 0.1 wt. % to about 2 wt. % of the weight of silver nanoparticles. Upon exposure to the high humidity treatment or atmosphere of the present disclosure, the capping agent is at least partially removed from the surface of the silver nanoparticles.

The humidity environment can be, for example, from about 40% relative humidity (RH) to about 100% RH; alternatively, from about 45% RH to about 95% RH; alternatively, from about 50% RH to about 80% RH, at a temperature from room temperature to less than 100° C. or from room temperature to about 80° C. alternatively, from room temperature to about 60° C. In specific examples, in order to demonstrate the concept the temperature is at room temperature and the humidity is room humidity, which is about 50-60% RH. Room temperature as used in the context of the present disclosure means a temperature that is between about 15° C. to 25° C.; alternatively, about 20° C. The annealed conductive trace can be exposed to the humidity treatment for a period of time ranging from about a few seconds to about a few weeks; alternatively, for about a couple of minutes to about a few days; alternatively, between about 1 minute and about 200 hours; alternatively, between about 10 minutes and 100 hours; alternatively, between about 1 hour and 24 hours.

Resistivity of the silver nanoparticle conductive trace can be measured using a 4-point probe method according to ASTM-F1529. According to one aspect of the present disclosure, the conductive trace after being subjected to a humidified atmosphere has a resistivity less than 5.0×10⁻⁵ ohms-cm; alternatively less than 1.0×10⁻⁵ ohms-cm; alternatively less than 8×10⁻⁶ ohms-cm. The ability to achieve low resistivity at a low processing temperature is desirable for many applications. The thickness of the silver nanoparticle conductive trace can be for example from about 100 nm to about 50 micrometers or microns, alternatively, from about 100 nm to about 20 microns, or alternatively, from about 1 micron to about 10 microns, depending on the methods used to apply the ink and the applications in which the conductive trace is utilized.

According to another aspect of the present disclosure, a functional conductive layered composite may be formed that comprises the conductive trace made and treated according to the teachings described above and further defined herein. For the purpose of this disclosure, the term “functional conductive layered composite” refers to any component, part, or composite structure that incorporates the conductive trace. The functional conductive layered composite may function as an antenna, an electrode of an electronic device, or an interconnect located between or joining two electronic components.

The method of forming a functional conductive layered composite comprises providing a plastic substrate; applying a primer layer to a surface of the plastic substrate; optionally, applying a primer layer to a surface of the plastic substrate and at least partially curing the primer layer; providing a silver nanoparticle ink; applying the silver nanoparticle ink onto the surface of the plastic substrate or onto the optional primer layer; annealing the silver nanoparticle ink at a temperature at or below 120° C. to form an initial conductive trace that exhibits a first resistivity (ρ₁); subjecting the initial conductive trace to a humidified atmosphere for a predetermined amount of time in order to form a treated conductive trace; the treated conductive trace exhibiting a second resistivity (ρ₂) that is less than ρ₁, alternatively, ρ₂ is less than ρ₁ by at least a factor of 2, alternatively, ρ₂ is less than ρ₁ by at least a factor of 10; and incorporating the treated conductive trace into the functional conductive layered composite.

The substrate used in the layered composite may be a polycarbonate, an acrylonitrile butadiene styrene (ABS), a polyamide, a polyester, a polyimide, vinyl polymer, polystyrene, polyether ether ketone (PEEK), polyurethane, epoxy-based polymer, polyethylene ether, polyether imide (PEI), polyolefin, a polyvinylidene fluoride (PVDF), PVDF copolymer, terpolymers such as P(VDF-trifluoroethylene), P(VDF-tetrafluoroethylene), poly(vinylidene fluoride-hexafluoropropylene) (P(VDF-HFP), poly(vinylidene fluoride-chlorotrifluoroethylene) (P(VDF-CTFE), poly(vinylidene fluoride-trifluoroethylene-chlorofluoroethylene) (P(VDF-TrFE-CFE)) and the like, or copolymer thereof. According to one aspect of the present disclosure, the substrate is not a porous substrate such as a paper substrate. Porous substrates may absorb the solvent or capping agent from the silver nanoparticle ink and reduce resistivity of conductive layer deposited on them, which is different from humidity effect disclosed herein. The silver nanoparticle ink comprises silver nanoparticles having an average particle diameter in the range of about 2 nanometers to about 800 nanometers (nm), alternatively, from about 50 nm to about 300 nm, and a surface that is at least partially stabilized with a hygroscopic or water-soluble capping agent. The average particle diameter of the silver nanoparticles in the conductive trace after annealing is substantially the same as that in the silver nanoparticle ink.

The capping agent as utilized with the silver nanoparticles in forming the functional conductive layered composite is selected from the group consisting of polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof. The capping agent is at least partially removed from the surface of the silver nanoparticles upon exposure to the humidified atmosphere comprising the humidity atmosphere comprising between about 40% relative humidity (RH) to about 100% RH at a temperature between about 20° C. to about 100° C. for the predetermined amount of time ranging between about 1 minute and about 200 hours.

Within this specification embodiments have been described in a way which enables a clear and concise specification to be written, but it in intended and will be appreciated that embodiments may be variously combined or separated without parting from the invention. For example, it will be appreciated that all preferred features described herein are applicable to all aspects of the invention described herein.

The following specific examples are given to further illustrate the preparation and testing of annealed conductive traces treated according to the teachings of the present disclosure and should not be construed to limit the scope of the disclosure. Those skilled-in-the-art, in light of the present disclosure, will appreciate that many changes can be made in the specific embodiments which are disclosed herein and still obtain alike or similar result without departing from or exceeding the spirit or scope of the disclosure.

### Example 1—Humidity Aging Treatment

A commercially available silver nanoparticle ink, namely, PG-007 (Pam Co. Ltd., South Korea) is used in this example. This silver nanoparticle ink comprises about 60 wt. % silver dispersed in mixed solvents of 1-methoxy-2-propanol (MOP) and ethylene glycol (EG). The silver nanoparticles have a particle size that is within the range of about 50 nm to about 300 nm with an overall average size between about 80-100 nm. The substrates in this example are Lexan 141R polycarbonate substrates (SABIC Innovative Plastics, Massachusetts).

The substrates were first cleaned with isopropanol (IPA), dried with compressed air, and optionally modified with plasma or a primer layer for adhesion improvement. The silver nanoparticle ink PG-007 was then applied on top of the substrate or the primer layer when present with a PA5363 applicator (BYK Gardner GmbH, Germany) having a 0.0508 mm (2-mil) gap. The wet films were dried at room temperature for about 10 minutes, then completely dried and annealed in a thermal oven at 120° C. for 60 minutes. It should be noted that the annealing temperature of 120° C. is determined by the properties exhibited by the low-cost and temperature-sensitive polycarbonate substrate.

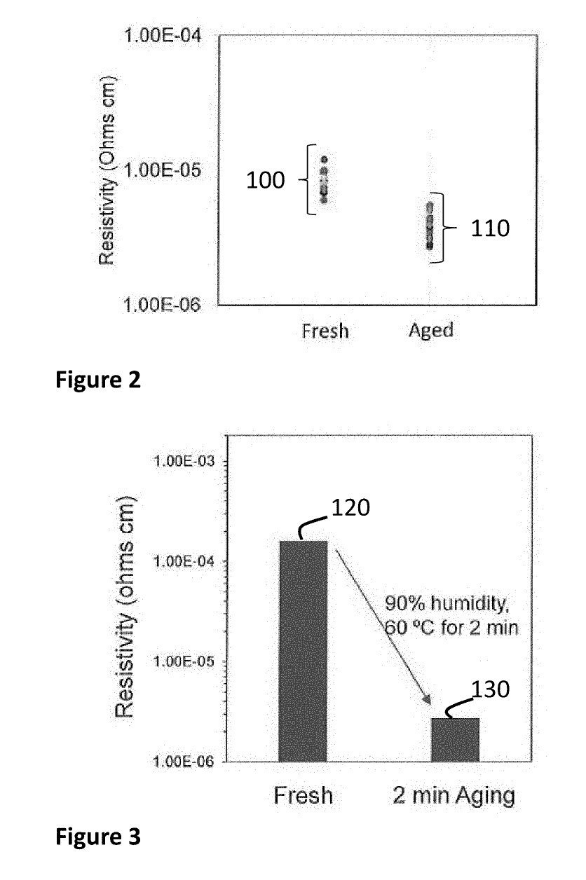

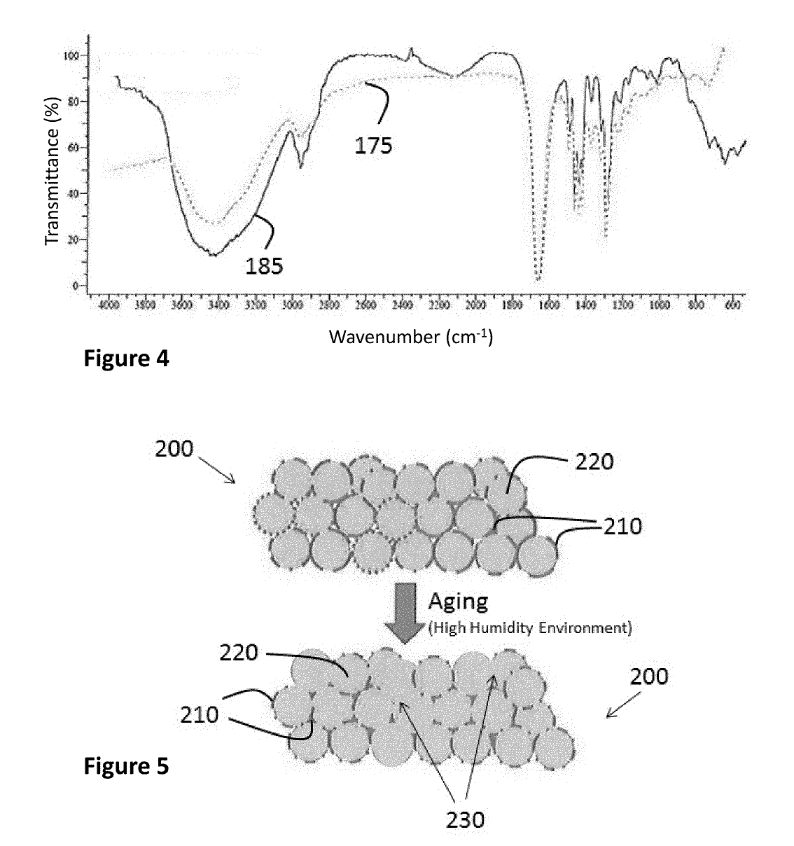

Resistivity of the annealed silver nanoparticle films were measured using a 4-point probe method according to ASTM-F1529. FIG. 2 summarizes the resistivity values for 20 samples that were prepared and tested. More specifically, the resistivity of the annealed silver nanoparticle films was measured before and after humidity aging for 24 hours. The fresh annealed films (100) exhibit a resistivity about 0.6-1.2×10⁻⁷ ohms-m with an average of 8.4×10⁻⁶ ohms-cm. After aging in a humidity chamber (90% RH, 60° C.) for 24 hours, the resistivity of the aged films (110) decreased by at least a factor of 2 to about 2.8-5.5×10⁻⁶ with an average of 4.0×10⁻⁶ ohms-cm. This decrease in resistivity is beneficial for many printed electronic applications, including without limitation, printed antenna applications, as low sheet resistance is desired for high RF efficiency.

### Example 2—Humidity Aging Treatment

A screen printable silver nanoparticle ink, PS-004 (Paru Co. Ltd., South Korea) was used in this example. This ink comprises about 80 wt. % silver nanoparticles having a particle size between 50 nm to 300 nm (with average size between 80 nm to 100 nm) dispersed in a diethylene glycol (DEG) solvent. The silver nanoparticle ink was screen printed on to a polyvinylidene fluoride (PVDF) substrate. Since the PVDF substrate was selected for use in a piezoelectric sensor application, the processing temperature for annealing the silver nanoparticle ink on the PVDF substrate was limited to no more than 80° C. After printing, the ink was dried at 80° C. for 10 minutes.

Referring now to FIG. 3, the resistivity was measured for this “fresh” film (120) to be 1.4×10⁻⁴ ohms-cm, which is about 3 times higher than the resistivity value of about 5.0×10⁻⁵ ohms-cm that is desirable for use in a sensor application. The silver nanoparticle film was then exposed to high humidity conditions (90% RH, 60° C.) for 2 minutes. Referring once again to FIG. 3, the resistivity of this “aged” film (130) decreased by about 2 orders of magnitude to the value of 2.6×10⁻⁶ ohms-cm.

### Example 3—Humidity and Temperature Ranges

In order to understand the effect of various humidity levels and temperatures on the resistivity exhibited by the conductive traces after exposure to the high humidity treatment, several dried silver films were exposed to various humidity conditions at different temperatures as shown in Table 1. The inks utilized included PG-007 and PS-004 (Pam Co. Ltd, South Korea). Since all of the samples exhibited a decrease in resistivity, a high humidity of 90% is not a mandatory condition. Rather, samples exposed to lower humidity, such as 70%, 60%, or even room humidity of 50-60% also exhibited a significant reduction in resistivity. In addition, an elevated temperature is not necessary in order to achieve a reduction in resistivity. Rather resistivity can be reduced even at room temperature. However, an elevated temperature may be desirable and selected for use in order to reduce the length of the associated exposure time.

The occurrence of resistivity reduction upon exposure of the conductive traces to a high humidity atmosphere is believed to be permanent and not reversible. More specifically, after drying the low resistivity film at 80° C., the film was observed to continue to exhibit a low resistivity (see Table 1). The films can also be dried at room temperature and still exhibit a reduction in resistivity upon being exposed to a high humidity atmosphere. In another words, low resistivity can be achieved with only room temperature processing, i.e., drying followed by exposure to humidity at room temperature.

TABLE 1
Resistivity change for samples dried and treated at
different conditions (humidity and temperatures).

| | | Resistivity | | Resistivity | |
|---|---|---|---|---|---|
| | | Before | | After | |
| | | Treatment | | Treatment | |
| Pastes | Drying | (ohms-cm) | Treatment Conditions | (ohms-cm) | Comments |
| PS-004 | 80° C. for | 1.60 × 10⁻⁴ | 90% RH at 60° C. for | 2.70 × 10⁻⁶ | Silver to yellow color |
| | 10 minutes | | 2 minutes | | change; yellow spots |
| PS-004 | 80° C. for | 7.70 × 10⁻⁵ | 70% RH at 40° C. for | 1.20 × 10⁻⁵ | Little to no color |
| | 20 minutes | | 2 minutes | | change; slightly |
| | | | | | reduced brightness |
| | | | 50-60% RH at R.T. for | 2.70 × 10⁻⁵ | No color change |
| | | | 48 hours | | |
| | | | 50-60% RH at R.T. for | 1.60 × 10⁻⁵ | Irreversible decrease |
| | | | 48 hours; again at 80° C. | | in resistivity |
| | | | for 10 minutes | | |
| PG-007 | 80° C. for | 4.70 × 10⁻⁴ | 50-60% RH at R.T. for | 5.50 × 10⁻⁵ | No color change |
| | 10 minutes | | 48 hours | | |
| | | | 50-60% RH at R.T. for | 4.30 × 10⁻⁵ | No color change |
| | | | 72 hours | | |
| PG-007 | RT for | 2.5 × 10⁻⁴ | 70% RH at 40° C. for 2 | 5.50 × 10⁻⁵ | Possible to dry |
| | 24 hours | | minutes | 3.40 × 10⁻⁵* | below 80° C. |

### Example 4—FTIR Analysis

Upon exposure to a high humidity environment, yellow spots were observed to form on top of the silver film. In order to better understand the fundamental reasons for the observed resistivity decrease, Fourier Transform Infrared (FTIR) spectroscopy was used to analyze the yellow spots. Referring now to FIG. 5, the FTIR spectrum of the yellow spot (175) matches well to the polyvinylpyrrolidone or PVP (185), which is a capping agent or stabilizer for the silver nanoparticles. PVP is also hygroscopic and a water soluble polymer.

Referring now to FIG. 5, without wanting to be limited to any theory, it is believe that exposure of the annealed silver nanoparticle films (200) to a high humidity environment leaches out or dissolves the water soluble capping polymer (210) present on the silver nanoparticle (220) surface, which leads to better particle to particle contact (230), thereby, reducing resistivity. In other words, “dissolving” the stabilizing agent (210) present on the silver nanoparticle (220) surface enhances particle to particle contact (230) and lower resistivity.

The preceding examples demonstrate a method of fabricating highly conductive features using silver nanoparticle inks at a low temperature predetermined by the properties associated with the substrate; alternatively, between room temperature and 120° C. This process is simple and straightforward, and can be easily integrated into a manufacturing process since no special chemicals and equipment are required. Conductive features fabricated and treated according to the teachings of the present disclosure can be used for many different applications such as antennas, electrodes for sensor, conductive traces for wearable devices or medical devices, or for applications wherein a low processing temperature is either desired or required.

The foregoing description of various forms of the invention has been presented for purposes of illustration and description. It is not intended to be exhaustive or to limit the invention to the precise forms disclosed. Numerous modifications or variations are possible in light of the above teachings. The forms discussed were chosen and described to provide the best illustration of the principles of the invention and its practical application to thereby enable one of ordinary skill in the art to utilize the invention in various forms and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. A method of forming a treated conductive trace on a substrate, the method comprising:
providing the substrate;
providing a silver nanoparticle ink;
applying the silver nanoparticle ink onto the substrate; and
annealing the silver nanoparticle ink to form an initial conductive trace having a first resistivity (ρ₁); and
subjecting the initial conductive trace to a humidified atmosphere for a predetermined amount of time in order to form the treated conductive trace having a second resistivity (ρ₂), wherein the ρ₂ is less than the ρ₁.

2. The method according to claim 1, wherein the humidity atmosphere comprises between about 40% relative humidity (RH) to about 100% RH at a temperature between about 20° C. to less than 100° C.

3. The method according to claim 1, wherein the predetermined amount of time is between about 1 minute and about 200 hours.

4. The method according to claim 1, wherein the method further comprises:
applying a primer layer to a surface of the substrate prior to the application of the silver nanoparticle ink; and
at least partially curing the primer layer;
wherein the silver nanoparticle ink is applied onto the surface of the primer layer.

5. The method according to claim 1, wherein ρ₂ is less than ρ₁ by at least a factor of 2.

6. The method according to claim 1, wherein the silver nanoparticle ink is annealed at a temperature no more than 120° C., and optionally, the method further comprises drying the treated conductive trace at a temperature ranging from room temperature up to about 80° C.

7. The method according to claim 1, wherein the silver nanoparticle ink comprises silver nanoparticles having an average particle diameter between about 2 nanometers and 800 nanometers.

8. The method according to claim 7, wherein the silver nanoparticles comprise a surface that is at least partially stabilized with a hygroscopic or water-soluble capping agent.

9. The method according to claim 1, wherein the silver nanoparticle ink is applied using an analog or a digital printing method.

10. The method according to claim 1, wherein the substrate is a plastic substrate formed from a polycarbonate, an acrylonitrile butadiene styrene (ABS), a polyamide, or a polyester, a polyimide, vinyl polymer, polystyrene, polyether ether ketone (PEEK), polyurethane, epoxy-based polymer, polyethylene ether, polyether imide (PEI), polyolefin, a polyvinylidene fluoride (PVDF), P(VDF-trifluoroethylene), P(VDF-tetrafluoroethylene), poly(vinylidene fluoride-hexafluoropropylene) (P(VDF-HFP), poly(vinylidene fluoride-chlorotrifluoroethylene) (P(VDF-CTFE), poly(vinylidene fluoride-trifluoroethylene-chlorofluoroethylene) (P(VDF-TrFE-CFE)) or a copolymer thereof.

11. The method according to claim 8, wherein the capping agent is at least partially removed from the surface of the silver nanoparticles upon exposure to the humidified atmosphere.

12. The method according to claim 8, wherein the capping agent is selected from the group consisting of polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof.

13. A functional conductive layered composite comprising the conductive trace formed according to the method of claim 1.

14. The functional conductive layered composite according to claim 13, wherein the functional conductive layered composite functions as an antenna, an electrode of an electronic device, or an interconnect between two electronic components.

15. A method of forming a functional conductive layered composite comprising:
providing a plastic substrate selected from the group consisting of a polycarbonate, an acrylonitrile butadiene styrene (ABS), a polyamide, a polyester, a polyimide, vinyl polymer, polystyrene, polyether ether ketone (PEEK), polyurethane, epoxy-based polymer, polyethylene ether, polyether imide (PEI), polyolefin, or a polyvinylidene fluoride (PVDF) substrate;
optionally, applying a primer layer to a surface of the plastic substrate and at least partially curing the primer layer;
providing a silver nanoparticle ink; the silver nanoparticle ink comprising silver nanoparticles having an average particle diameter in the range of about 2 nanometers to about 800 nanometers and a surface that is at least partially stabilized with a hygroscopic or water-soluble capping agent;
applying the silver nanoparticle ink onto the surface of the plastic substrate or onto the optional primer layer; and
annealing the silver nanoparticle ink at a temperature at or below 120° C. to form an initial conductive trace that exhibits a first resistivity (ρ₁); and
subjecting the initial conductive trace to a humidified atmosphere for a predetermined amount of time in order to form a treated conductive trace; the treated conductive trace exhibiting a second resistivity (ρ₂) that is less than ρ₁;
optionally, drying the treated conductive trace; and
incorporating the conductive trace into the functional conductive layered composite.

16. The method according to claim 15, wherein the humidity atmosphere comprises between about 40% relative humidity (RH) to about 100% RH at a temperature between about 20° C. to about 100° C.; wherein the predetermined amount of time is between about 1 minute and about 200 hours.

17. The method according to claim 15, wherein the capping agent is at least partially removed from the surface of the silver nanoparticles upon exposure to the humidified atmosphere.

18. The method according to claim 15, wherein ρ₂ is less than ρ₁ by at least a factor of 2.

19. The method according to claim 15, wherein the capping agent is selected from the group consisting of polyvinylpyrrolidone (PVP), polyvinyl alcohol (PVA), polyethyleneimine, hydroxyl cellulose, polyethylene glycol (PEG), polyethylene oxide (PEO), poly(acrylic acid), or a mixture thereof.

20. The method of claim 15, wherein the silver nanoparticles have an average particle size from about 50 nm to about 300 nm, and ρ₂ is less than ρ₁ by at least a factor of 10.
